(19) United States
(12) Patent Application Publication
(10) Pub. No.: US 2007/0264519 A1
(43) Pub. Date: Nov. 15, 2007

(54) Copper-pillar plugs for semiconductor die

(75) Inventor: Daniel M. Kinzer, El Segundo, CA (US)

Correspondence Address: OSTROLENK FABER GERB & SOFFEN, 1180 AVENUE OF THE AMERICAS, NEW YORK, NY, 100368403, US

(73) Assignee: International Rectifier Corporation

(21) Appl. No.: 11/717,491

(22) Filed: Mar. 13, 2007

Related U.S. Application Data
(60) Provisional application No. 60/798,985, filed on May 9, 2006.

(51) Int. Cl. H01L 23/535

(52) U.S. Cl. 428/598; 428/67

(57) ABSTRACT

A plurality of small diameter, closely spaced openings are formed in the back of a semiconductor wafer and are filled with copper plugs in areas of the wafer where the effect of thinning is desired. The openings may be holes of any desired cross-section with a width or diameter of 3 to 5 μm and a center-to-center spacing of about 50 μm. The posts can have a depth of 180 μm or greater in a wafer having a thickness of 200 μm or greater. The wafer can be silicon, silicon carbide, gallium nitride, or any substrate used for semiconductor device fabrication.

### RELATED APPLICATIONS

This application claims the benefit of U.S. Provisional Application No. 60/798,985, filed May 9, 2006, the entire disclosure of which is incorporated by reference herein.

### FIELD OF THE INVENTION

This invention relates to semiconductor devices and processes for their manufacture in which the wafer has the characteristics of a thinned wafer.

### BACKGROUND OF THE INVENTION

MOSGATED devices such as planar and trench power MOSFETs and IGBTs have an on-resistance which includes the substrate resistance as a component thereof. Such devices are formed in semiconductor wafers such as silicon, SiC, III Nitride wafers and the like. It is known to reduce the thickness of the wafer, for example, from 380μ or more to 80μ or less to reduce R_{DSON} of the die separated therefrom as well as to obtain other benefits. Thus, most junction-forming steps are performed on the top surface of the wafer before thinning. The top surface is then covered with a protective layer and the wafer thickness is reduced by backgrinding and/or etching the full or a part of the rear surface of the wafer. The back metal is then applied to the back surface and the die are singulated.

It is very difficult to handle wafers after they are reduced in thickness to, for example, 80μ or less and considerable breakage is encountered in the processing steps for thinning the wafer and applying the back metal.

It would be very desirable to have a process by which wafers can be thinned to reduce substrate electrical resistance and thermal resistance and yet be rugged enough to withstand handling without excess breakage.

Copending application Ser. No. 11/194,815, filed Aug. 1, 2005 entitled SELECTIVE SUBSTRATE THINNING FOR POWER MOSGATED DEVICES (IR-2342) describes a process in which, wafers are first processed in the usual manner to form the top surface junction patterns. Such wafers are for vertical conduction devices, such as planar or trench type MOSFETs. Thereafter, the wafer thickness is partially reduced, as by a back surface grind to a thickness which is still large enough to withstand wafer handling stress without excess breakage. The back surface is next patterned as by an oxide mask or photoresist only, to define an etch window under only selected portions of the wafer area, for example, the active area or areas, and leaving thicker unetched webs, as in the wafer streets. By initially partially backgrinding the wafer, the thickness to be etched is reduced. However, the partial backgrinding step can be eliminated if desired. The mask is then stripped and a back metal is then deposited on the full wafer back side and into the etched depressions or openings.

By thinning the wafer under the active vertical conduction areas, the R_{DSON} of the ultimately formed MOSFET die is reduced, while the thickened web or unetched portions of the wafer or die provide sufficient strength to the wafer to better resist breakage during handling.

It would be desirable to provide a process in which the strength of the resulting thinned wafer is even further increased.

### BRIEF DESCRIPTION OF THE INVENTION

In accordance with the invention, a plurality of small diameter, closely spaced openings are formed into the back of the wafer and extend to or close to the upper surface of the wafer, in the area or areas where wafer “thinning” is desired. These openings are then filled with copper posts or posts of other high electrical and thermal conductivity materials, by a suitable deposition process into the back surface of the wafer.

By way of example, the openings or holes may have a diameter of 3 to 5 μm and a pitch or center-to-center spacing of about 25-50 μm. The posts can have a depth, typically of 180 μm or greater in a wafer having a thickness of typically 200 μm or greater.

The conductive posts will then act as excellent electrical and/or thermal conductors, carrying current and/or heat from the top junction-containing surface of the wafer/die to the bottom electrode and to heat sinks associated therewith, thus reducing R_{DSON} of vertical conduction devices with improved cooling.

### BRIEF DESCRIPTION OF THE DRAWINGS

FIG. 1 shows a small portion of an active area of a wafer, in cross-section, having the conductive posts in one embodiment of the invention.

### DETAIL DESCRIPTION OF THE DRAWING

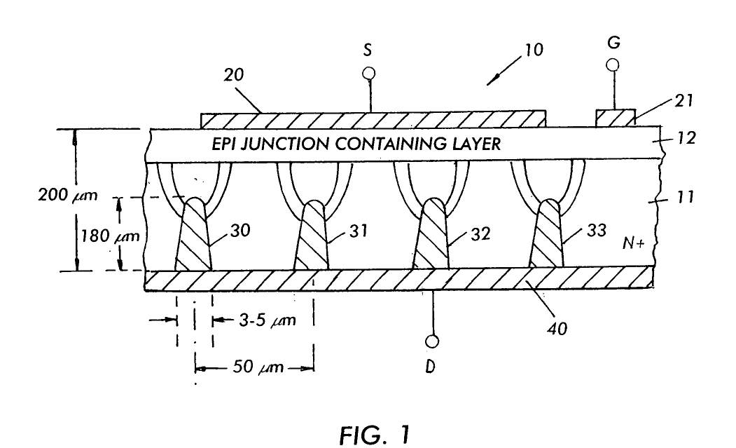

Referring to FIG. 1, there is shown a wafer 10, which may be silicon, or a III nitride device wafer or the like. Note that the wafer 10 could be a single large area intended to be singulated into a plurality of separate die, or may also be a single die which has been singulated from a larger area wafer.

The wafer 10 may, in one embodiment, be silicon, having an N+ bulk region 11 which has a junction-receiving epitaxially deposited layer 12 on its top surface. The bulk region 11 may have a thickness of about 200 μm or greater to retain mechanical strength and rigidity, and the epitaxial silicon layer 12 may have a thickness of 5 μm or more, depending on the type device to be formed. Further, the bulk wafer may be CZ (czochralski) silicon having a resistivity of 0.001 ohm-cm, heavily doped with Arsenic or Phosphorus.

The initial bulk wafer 11 may have had a thickness of about 350 μm to 700 μm and all process steps to form the necessary junctions (not shown) in epi layer 12 are performed in the thicker wafer. The top of the wafer may have exemplary electrodes formed thereon, such as source electrode 20 and gate electrode 21. The back side of the wafer has been thereafter ground to thin the wafer, for example, to 200 μm thick. This could vary across a wide range, such as from 50μ to 400μ, and the technique could still provide benefit.

A plurality of closely spaced holes 30, 31, 32, 33 (any number can be used) are then etched into the back surface of the wafer, preferably in this active area of the die. These holes may be circular, oval, or even elongated parallel trenches (in cross-section). The spacing of the holes should be less than the wafer thickness, to reduce the path length of current flow to the nearest low resistance conductor.

The diameter (or width) of the holes 30, 31, 32, 33 is typically about 3 to 5 μm, and their depth is about 180 μm (or greater) in a 200 μm thick wafer. The diameter and density of holes should be large enough to provide a substantial reduction in vertical resistance compared to the bulk wafer. Since copper is ˜500× more conductive than silicon, a copper cross-sectional area of 1% of the total area will reduce substrate resistance by a factor of 5, for example. Preferably the total area of all posts will be greater than about 1% but less than about 50% of the wafer area. Further, the post heights will terminate not extend into the epitaxial layer 12 or any high field region of the device. The holes are then filled with copper or some other highly conductive material, compared to the conductivity of the bulk wafer. Other materials with excellent thermal and/or electrical conduction characteristics could also be used. This can be done by sputtering a seed layer on the trench sidewall, and then electroplating copper to fill the holes.

A conductive drain electrode 40 is then connected to the bottom of the wafer 10 and in contact with the bottom posts 30 to 33.

Thus, in operation, the posts 30 to 33 will act to improve the electrical and/or thermal characteristics of the device as in prior art thinned wafers, while leaving the wafer with sufficient mechanical strength to receive subsequent conventional processing including die singulation and packaging with reduced danger of damage.

Although the present invention has been described in relation to particular embodiments thereof, many other variations and modifications and other uses will become apparent to those skilled in the art. It is preferred, therefore, that the present invention be limited not by the specific disclosure herein.

What is claimed is:

1. A semiconductor device wafer having the reduced substrate resistance characteristics of a severely thinned wafer, but retaining substantial strength against fracture; said wafer having a semiconductor body with flat parallel opposing top and bottom surfaces; a semiconductor pattern formed in the top surface of said body; a plurality of spaced parallel posts of material having high thermal and electrical conductivity compared to the thermal and electrical conductivity of said semiconductor body, extending into said semiconductor body from its said bottom surface and extending to a given height into said body; said posts capable of conducting electrical current and thermal energy from said top surface to said bottom surface, while allowing the strength and other mechanical attributes of a thicker wafer to be preserved.

2. The wafer of claim 1, wherein the top of said semiconductor body consists of an epitaxially formed, junction receiving body.

3. The wafer of claim 2, wherein said posts are copper.

4. The wafer of claim 2, wherein said body has a thickness of about 200 μm and said posts have a length of about 180 μm.

5. The wafer of claim 1, wherein said posts have a width or diameter of about 3 to 5 μm and a center-to-center spacing of about 25-50 μm.

6. The wafer of claim 2, wherein said posts have a width or diameter of about 3 to 5 μm and a center-to-center spacing of about 25-50 μm.

7. The wafer of claim 5, wherein said posts are copper.

8. The wafer of claim 4, wherein said posts have a width or diameter of about 3 to 5 μm and a center-to-center spacing of about 25-50 cm.

9. The wafer of claim 1, wherein said semiconductor body is a material selected from the group consisting of silicon, III nitride, and silicon carbide.

10. The wafer of claim 9, wherein the top of said body consists of an epitaxially formed, junction receiving body.

11. The wafer of claim 9, wherein said posts are copper.

12. The wafer of claim 9, wherein said body has a thickness of about 200 μm and said posts have a length of about 180 μm.

13. The wafer of claim 9, wherein said posts have a width or diameter of about 3 to 5 μm and a center-to-center spacing of about 25-50 cm.

14. The wafer of claim 12, wherein said posts have a width/diameter of about 3 to 5 μm and a center-to-center spacing of about 25-50 μm.

15. The wafer of claim 1, wherein the total current carrying area of said posts is between about 1% to about 50% of the total area of said wafer.

16. The wafer of claim 2, wherein said posts have a height measured from the bottom surface of said wafer which is greater than about 30% of the wafer thickness, but wherein the tops of said posts fall short of said junction containing layer.

17. The wafer of claim 16, wherein the total current carrying area of said posts is between about 1% to about 50% of the total area of said wafer.

18. The wafer of claim 17, wherein said posts have a width or diameter of about 3 to 5 μm and a center-to-center spacing of about 25-50 μm.
